(19) United States
(12) Patent Application Publication
(10) Pub. No.: US 2008/0164893 A1
(43) Pub. Date: Jul. 10, 2008

(54) Probe card for testing wafer

(75) Inventors: Hyun-ae Lee, Gyeonggi-do (KR); Ho-jeong Choi, Gyeonggi-do (KR)

Correspondence Address: MILLS & ONELLO LLP, ELEVEN BEACON STREET, SUITE 605, BOSTON, MA, 02108, US

(73) Assignee: Samsung Electronics Co., Ltd., Suwon-si (KR)

(21) Appl. No.: 11/901,868

(22) Filed: Sep. 19, 2007

(30) Foreign Application Priority Data
Jan. 4, 2007 (KR) 10-2007-0001184

(51) Int. Cl. G01R 1/04; G01R 31/26

(52) U.S. Cl. 324/754

(57) ABSTRACT

Provided is a probe card for testing a wafer. The probe card includes: a main card having a flat plate in which a hole is formed; an auxiliary card vertically mounted on the main card through the hole; and a plurality of probe needles attached to the auxiliary card. Costs and time for manufacturing the probe card are greatly reduced.

### CROSS-REFERENCE TO RELATED PATENT APPLICATIONS

This application claims the benefit of Korean Patent Application No. 10-2007-0001184, filed on Jan. 4, 2007, in the Korean Intellectual Property Office, the contents of which is incorporated herein in its entirety by reference.

### BACKGROUND OF THE INVENTION

1. Field of the Invention

The present invention relates to a semiconductor test apparatus, and more particularly, to a probe card for testing a plurality of integrated circuit (IC) devices disposed on a wafer.

2. Description of the Related Art

Integrated circuit (IC) devices are fabricated through processes, such as a process of manufacturing a thin wafer, a process of manufacturing a plurality of IC chips in the wafer, an electrical die sort (EDS) process of determining whether the IC chips are defective, a process of manufacturing a semiconductor package by packaging the IC chips, and a process of testing the semiconductor package.

Among the processes, in the EDS process, electrical signals are applied to the IC chips disposed on the wafer, so as to test the function of the IC chips, and non-defective IC chips and defective IC chips are identified and the defective IC chips are marked with ink. In a subsequent process of manufacturing the semiconductor package, only non-defective chips are sorted and packaged so that costs and time for manufacturing the semiconductor package are reduced.

In order to perform the EDS process, test equipment for supplying electrical signals to the plurality of IC chips disposed on the wafer, receiving electrical signals transmitted from the IC chips and determining the electrical performance of the IC chips, and a probe card connected to the test equipment and the IC chips and transmitting electrical signals between the test equipment and the IC chips must be provided.

FIG. 1 is a schematic plan view of a conventional probe card, and FIG. 2 is a side view of the probe card illustrated in FIG. 1. Referring to FIGS. 1 and 2, the conventional probe card 101 includes a circuit board 121 and a plurality of probe needles 131.

The circuit board 121 includes a plurality of connection portions 125 that are electrically connected to the test equipment. The plurality of connection portions 125 are electrically connected to the plurality of probe needles 131 through a plurality of conductors (not shown) arranged on the circuit board 121.

The plurality of probe needles 131 are attached to supports 141 installed on the circuit board 121. The plurality of probe needles 131 are connected to the circuit board 121 through electrical wires 151. During a wafer test, the plurality of probe needles 131 contact a plurality of pads respectively formed in the plurality of IC chips disposed on the wafer.

There are a variety of conventional probe cards 101 categorized according to the types of the IC chips. The arrangement state and number of the plurality of pads formed in the IC chips vary according to types of the IC chips. The arrangement and number of the plurality of probe needles 131 vary according to various arrangement and numbers of the pads. In this way, as the arrangement and number of the plurality of probe needles 131 vary, the probe cards 101 vary.

As described above, as types of IC chips vary, the probe cards 101 vary so that costs for manufacturing the probe card 101 are high. In addition, when the number of probe needles 131 is large, a time for manufacturing the probe card 101 becomes long, test duration is increased and productivity is lowered.

### SUMMARY OF THE INVENTION

The present invention provides a probe card in which manufacturing costs and the time of manufacturing are greatly reduced.

According to an aspect of the present invention, there is provided a probe card, the probe card comprising a main card having a flat plate, a hole being formed in the flat plate. An auxiliary card is vertically mounted on the main card through the hole, and a plurality of probe needles are attached to the auxiliary card.

The auxiliary card may be mounted on and detached from the main card.

The probe card may include a substrate mounting portion installed on the main card, combined with the auxiliary card and fixing the auxiliary card on the main card.

A plurality of auxiliary cards may be mounted on the main card.

The probe card may be used in testing an IC (integrated circuit) chip disposed on a wafer.

The main card may include a plurality of electrical conductors and the auxiliary card may include a plurality of connection portions for electrically connecting the plurality of electrical conductors to the plurality of probe needles.

The auxiliary card may further include a plurality of wires for electrically connecting the plurality of connection portions to the plurality of probe needles.

The plurality of connection portions may be connectors that can be connected to and detached from the plurality of probe needles.

The plurality of probe needles may be formed in a straight line shape.

The auxiliary card may further include a plurality of needle pedestals, the plurality of needle pedestals provided between the plurality of needles and the auxiliary card and supporting the plurality of needles upwards so that the plurality of needles can be inclined with respect to the auxiliary card.

According to another aspect of the present invention, there is provided a probe card, the probe card comprising a main card having a flat plate in which a hole is formed. An auxiliary card is vertically mounted on the main card through the hole. A plurality of probe needles are attached to the auxiliary card. An adjusting portion is installed above the main card and moves the auxiliary card forward and backward.

The main card may be installed on the adjusting portion and may include a substrate mounting portion on which the auxiliary card is mounted.

The main card may include a pedestal installed below the adjusting portion and fixing the adjusting portion on the main card.

A plurality of auxiliary cards and a plurality of adjusting portions may be respectively provided.

According to another aspect of the present invention, there is provided a probe card, the probe card comprising a main card having a flat plate in which a hole is formed. An auxiliary card is vertically mounted on the main card through the hole. A plurality of probe needles are attached to the auxiliary card. An X-axis adjusting portion is installed above the main card and moving the auxiliary card in an X-axis. A Y-axis adjusting portion installed below the X-axis adjusting portion and moving the X-axis adjusting portion in an Y-axis.

The main card may be installed on the X-axis adjusting portion and may include a substrate mounting portion on which the auxiliary card is mounted.

The main card may include a pedestal installed below the Y-axis adjusting portion and fixing the Y-axis adjusting portion on the main card.

A plurality of auxiliary cards, a plurality of X-axis adjusting portions, and a plurality of Y-axis adjusting portions may be respectively provided.

According to another aspect of the present invention, there is provided a probe card, the probe card comprising: a main card having a flat plate in which a hole is formed. An auxiliary card is vertically mounted on the main card through the hole. A plurality of probe needles attached to the auxiliary card; a probe needle which is attached to the auxiliary card and to which a power supply voltage is applied; and a power restricting portion electrically connected to the probe needle to which the power supply voltage is applied and preventing an overvoltage or overcurrent from being applied to the probe needle to which the power supply voltage is applied.

The power restricting portion may be a capacitor.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention.

FIG. 1 is a schematic plan view of a conventional probe card.

FIG. 2 is a side view of the probe card illustrated in FIG. 1.

FIG. 3 is a perspective view of a probe card according to an embodiment of the present invention.

FIG. 4 is a schematic cross-sectional side view taken along line A-A′ of the probe card illustrated in FIG. 3.

FIG. 5 is a front view of an auxiliary card illustrated in FIG. 3.

FIG. 6 is a side view of the auxiliary card illustrated in FIG. 5.

FIG. 7 illustrates an IC chip in which a plurality of pads are arranged in one column at one surface of the IC chip.

FIG. 8 is a side view of an auxiliary card illustrating a probe needle for transmitting a power supply voltage of a plurality of probe needles illustrated in FIG. 6.

FIG. 9 illustrates another example of the auxiliary card illustrated in FIG. 6.

FIG. 10 illustrates an IC chip in which a plurality of pads are arranged in a plurality of columns at one surface of the IC chip.

### DETAILED DESCRIPTION OF PREFERRED EMBODIMENTS OF THE INVENTION

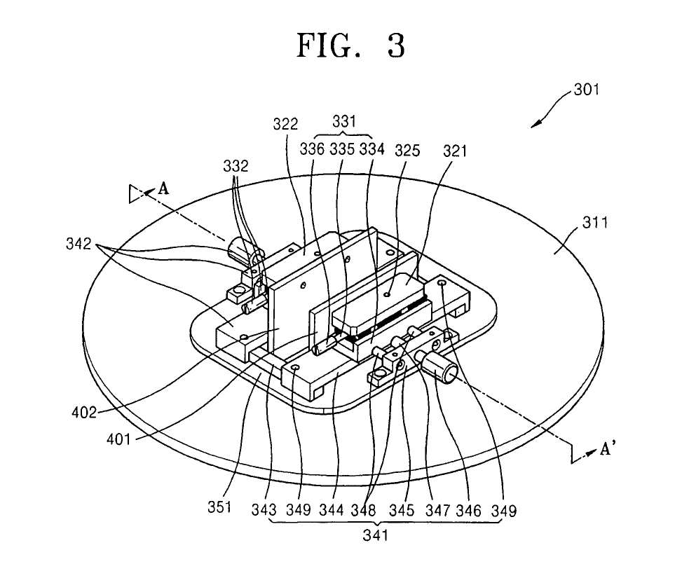

FIG. 3 is a perspective view of a probe card according to an embodiment of the present invention. Referring to FIG. 3, a probe card 301 includes main card 311˜351 and a plurality of auxiliary cards 401 and 402.

The main card 311˜351 includes a circuit board 311, a pedestal 351, a plurality of substrate mounting portions 321 and 322, a plurality of Y-axis adjusting portions 331 and 332, and a plurality of X-axis adjusting portions 341 and 342. Each of the plurality of substrate mounting portions 321 and 322, the plurality of Y-axis adjusting portions 331 and 332 and the plurality of X-axis adjusting portions 341 and 342 has the same configuration. Thus, for the purpose of clarity of description, these elements will be described in association with the substrate mounting portion 321, the Y-axis adjusting portion 331, and the X-axis adjusting portion 341 illustrated on the right of FIG. 3.

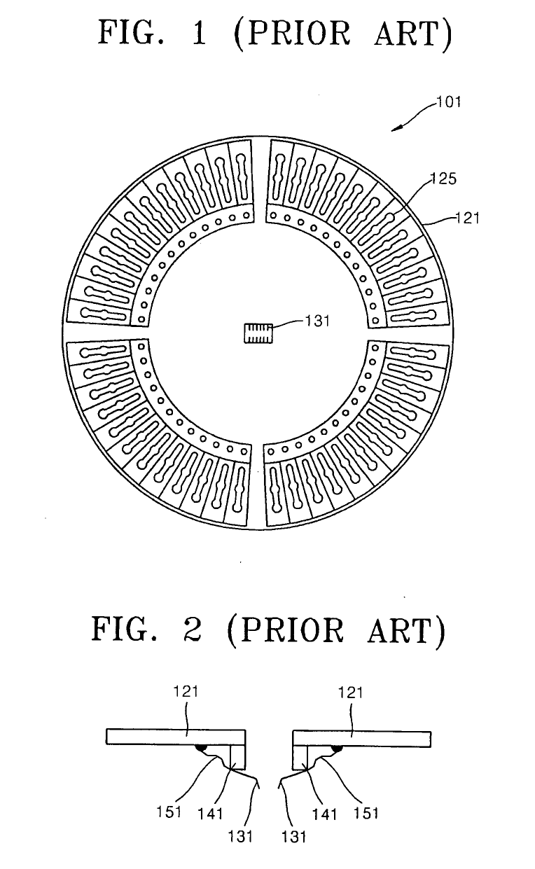

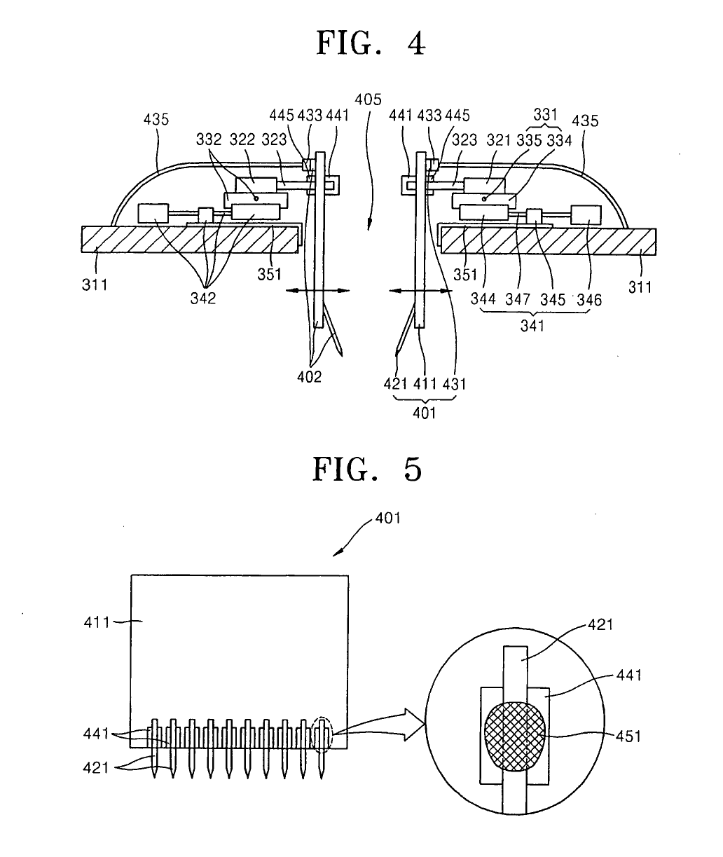

The circuit board 311 is a solid substrate. A plurality of connection portions (125 of FIG. 1) electrically connected to test equipment (not shown) and a plurality of conductors (not shown) for electrically connecting the plurality of connection portions (125 of FIG. 1) to an auxiliary card (401 of FIG. 4) are disposed on the circuit board 311. The number of the plurality of connection portions (125 of FIG. 1) and the number of the plurality of conductors (not shown) are proportional to the number of a plurality of pads (711 of FIG. 7) provided at an IC chip (701 of FIG. 7). A rectangular hole (405 of FIG. 4) can be formed in the circuit board 311, e.g., in the middle of the circuit board 311. The auxiliary card 401 is mounted on the substrate mounting portion 321 through the hole (405 of FIG. 4).

The pedestal 351 is mounted on the circuit board 311. Without the pedestal, since the plurality of conductors are formed on the circuit board 311, when the Y-axis adjusting portion 331 is directly installed on the circuit board 311, the plurality of conductors may be damaged. The pedestal 351 is used so as to prevent damage to the plurality of conductors. In addition, the pedestal 351 is formed of a solid material and an upper portion thereof is flat. Thus, the X-axis adjusting portion 341 is installed on the pedestal 351 and is fixed so as not to move. The X-axis adjusting portion 341, the Y-axis adjusting portion 331, and the substrate mounting portion 321 are sequentially stacked on the pedestal 351.

The substrate mounting portion 321 is installed on the Y-axis adjusting portion 331. The substrate mounting portion 321 is fixed on the Y-axis adjusting portion 331 by a fastening means such as a screw, so as not to move in the state it is installed on the Y-axis adjusting portion 331. The auxiliary card 401 is mounted on the substrate mounting portion 321. The auxiliary card 401 mounted on the substrate mounting portion 321 is fixed by a fastening means (441 of FIG. 4) so as not to move. The auxiliary card 401 is easily mounted on the substrate mounting portion 321 and is easily detached therefrom by the fastening means (441 of FIG. 4).

The Y-axis adjusting portion 331 is installed on the X-axis adjusting portion 341. The Y-axis adjusting portion 331 is fixed on the X-axis adjusting portion 341 by a fastening means such as a screw. The Y-axis adjusting portion 331 includes a first slice 334, a first lever 335, and a first handle 336. The first lever 335 is long in a cylindrical shape, and part thereof is formed in a screw shape. The screw-shaped part of the first lever 335 is inserted into the first slice 334. Thus, if the first lever 335 is rotated right or left, the first slice 334 makes a reciprocal motion in the Y-axis.

The first handle 336 is connected to one end of the first lever 335. A user can easily rotate the first lever 335 using the first handle 336. The first slice 334 is mounted on the second slice 344 and makes a reciprocal motion in the Y-axis based on the second slice 344. If the first slice 334 moves to the Y-axis, the substrate mounting portion 321 also moves in the Y-axis. A moving distance of the first slice 334 is set in consideration of the length of the hole (405 of FIG. 4) and the size of the auxiliary card 401.

A first stopper 325 is installed on the first slice 334. When the user wants to move the first slice 334, the user lifts the first stopper 325 to open it, and when the user wants to fix the first slice 334 in a predetermined position, the user presses the first stopper 325 to lock it.

The X-axis adjusting portion 341 is installed on the pedestal 351. The X-axis adjusting portion 341 includes two rails 343, a second slice 344, a second lever 347, a plurality of support levers 348, a second handle 346, and a second handle fixing portion 345.

The plurality of rails 343 are installed at both ends of the second slice 344. The second slice 344 is installed on the plurality of rails 343. Thus, the second slice 344 can make a reciprocal motion in the X-axis along the plurality of rails 343. The second lever 347 is inserted into the second slice 344. Part of the second lever 347 is formed in a screw shape. Thus, if the second lever 347 is rotated, the second slice 344 makes a reciprocal motion in the X-axis along the plurality of rails 343. One end of the second lever 347 is connected to the second handle 346 through a hole formed in the second handle fixing portion 345. Thus, the second lever 347 is supported horizontally so that a deviation does not occur when the second slice 344 makes a reciprocal motion. The user can easily rotate the second lever 347 using the second handle 346.

Since the second slice 344 is lager than the first slice 334, a small deviation may occur when the second slice 344 makes a reciprocal motion. To prevent the deviation, a plurality of support levers 348 are provided. The plurality of support levers 348 are fixed on the second slice 344 and one ends thereof pass into holes formed in both sides of the second handle fixing portion 345. In this case, a gap between outer surfaces of the plurality of support levers 348 and the holes of the second handle fixing portion 345 must not be formed. Thus, a deviation that may occur when the second slice 344 makes a reciprocal motion can be prevented.

A second stopper 349 is installed on the second slice 344. When the user wants to move the second slice 344, the user lifts the second stopper 349 to open it, and when the user wants to fix the second slice 344 in a predetermined position, the user presses the second stopper 349 to lock it.

As described above, the main card 311˜351 includes the X-axis adjusting portion 341 and the Y-axis adjusting portion 331 so that the auxiliary card 401 mounted on the substrate mounting portion 321 can be moved in the X-axis and the Y-axis.

A plurality of needles (421 of FIG. 4) are installed at the auxiliary card 401. The plurality of needles (421 of FIG. 4) contact a plurality of pads formed on the IC chip, so as to test the IC chip disposed on the wafer. Since the pads are very small, it is very difficult to precisely contact the plurality of needles (421 of FIG. 4) to the plurality of pads. Thus, positions of the plurality of needles (421 of FIG. 4) are precisely adjusted using the X-axis adjusting portion 341 and the Y-axis adjusting portion 331 of the present invention so that the plurality of needles (421 of FIG. 4) can precisely contact the plurality of pads.

FIG. 4 is a cross-sectional view taken along line A-A′ of the probe card 301 of FIG. 3. Referring to FIG. 4, a plurality of auxiliary cards 401 and 402 are vertically mounted on the main card 311˜351 through the hole 405. Since the plurality of auxiliary cards 401 and 402 are symmetrical with each other with respect to the hole 405, for convenience of description, only a portion illustrated in the right of FIG. 4 will now be described.

A support 323 is installed at the substrate mounting portion 321. When the auxiliary card 401 is mounted on the substrate mounting portion 321, the support 323 perforates holes formed in the auxiliary card 401 and then, the protruded support 323 is fastened by a fastening portion 441 so that the auxiliary card 401 is mounted on the substrate mounting portion 321. In this case, a stopper 445 is installed on the support 323 so that the auxiliary card 401 is fixed between the stopper 445 and the fastening portion 441.

FIG. 5 is a front view of the auxiliary card illustrated in FIG. 3. Referring to FIG. 5, the auxiliary card includes a circuit board 411, a plurality of probe needles 421, and a plurality of needle pedestals 441.

The circuit board 411 is manufactured of an insulating material such as reinforced fabric glass or plastics. The circuit board 411 may be formed in a single layer or in multiple layers. When the number of the probe needles 421 attached to the circuit board 411 is small, the construction of conductors (not shown) formed on the circuit board 411 is simplified. In this case, the circuit board 411 is formed in a single layer. When the number of the probe needles 421 attached to the circuit board 411 is large, the construction of conductors formed on the circuit board 411 is complicated. In this case, the circuit board 411 is formed in multiple layers. When the circuit board 411 is formed in multiple layers, part or all of the wires are disposed in the circuit board 411 so as not to be exposed to the outside.

When one end of the circuit board 411, that is, the circuit board 411 is vertically mounted on the main card (311˜351 of FIG. 3), the plurality of probe needles 421 are attached to a lower portion of the circuit board 411. Each of the probe needles 421 has a very small resistance and is formed of a material having solidity, for example, tungsten. The probe needles 421 are formed in a straight line shape without curved portions.

The plurality of needle pedestals 441 pedestal the plurality of needles 421 to be fixed in one direction in the state where the plurality of needles 421 are attached to the circuit board 411. The plurality of needles 421 are adhered to the plurality of needle pedestals 441 by adhesive members 451. Thus, the plurality of probe needles 421 are fixed in one direction.

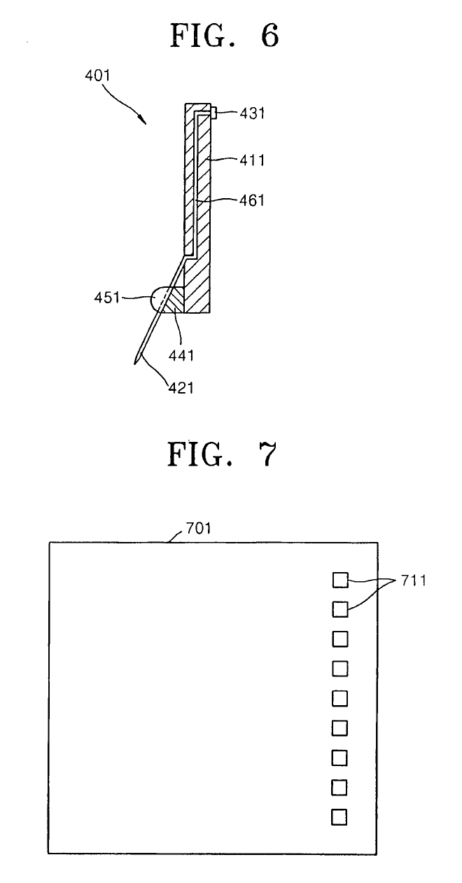

FIG. 6 is a side view of the auxiliary card illustrated in FIG. 5. Referring to FIG. 6, each probe needle 421 is not parallel to the circuit board 411 and is inclined at a larger angle than “zero” degree with respect to the circuit board 411. In addition, each probe needle 421 is connected to a connection portion 431 through a conductor 461 formed on the circuit board 411. The connection portion 431 is connected to an electrical wire (445 of FIG. 4). Thus, each probe needle 421 is electrically connected to the main card (311˜351 of FIG. 30 through the conductor 461 and the connection portion 431. The connection portion 431 is formed as a socket and a connector (433 of FIG. 4) is connected to an end of the electrical wire (435 of FIG. 4) so that the connection portion 431 and the electrical conductor (435 of FIG. 4) can be easily connected to each Other and detached from each other. When the circuit board 411 is formed in multiple layers, the conductor 461 is disposed in the circuit board 411.

The plurality of probe needles 421 arranged in one column are suitable for the case where an IC chip 701 in which a plurality of pads 711 are arranged in one column at one surface of the IC chip 701, as illustrated in FIG. 7, is tested.

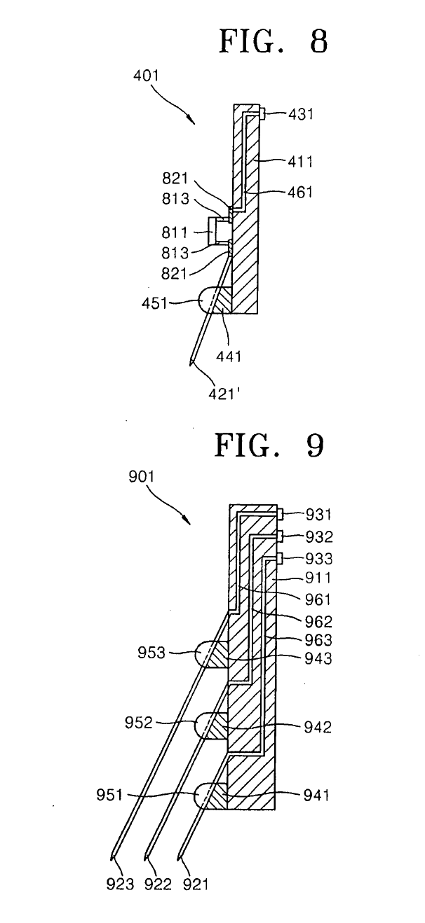

FIG. 8 is a side view of an auxiliary card illustrating a probe needle 421′ for transmitting a power supply voltage of the plurality of probe needles 421 illustrated in FIG. 6. Referring to FIG. 8, conductors 461 and 821 are formed on the circuit board 411, and a power restricting portion 811 is connected to the conductors 821. Thus, the probe needle 421′ for transmitting the power supply voltage is electrically connected to the connection portion 431 through the conductors 821, the conductor 461, and the power restricting portion 811. The power restricting portion 811 prevents an overvoltage or overcurrent from being applied to the probe needle 421′ for transmitting the power supply voltage. The power restricting portion 811 includes a capacitor or resistor.

In this way, the power restricting portion 811 is connected to be close to the probe needle 421′ for transmitting the power supply voltage so that an overvoltage or overcurrent cannot be applied to the probe needle 421′ to which the power supply voltage is applied. Thus, the life span of the probe needle 421′ is lengthened.

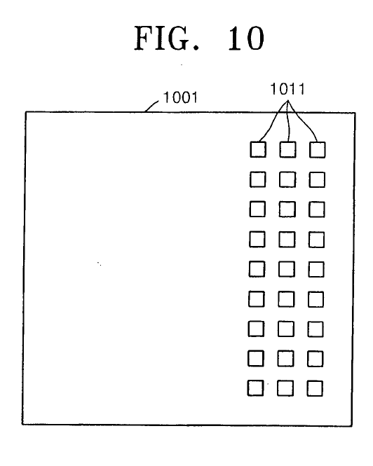

FIG. 9 illustrates another example of the auxiliary card 401 illustrated in FIG. 6. Referring to FIG. 9, an auxiliary card 901 includes a plurality of probe needles 921˜923 arranged in three columns up and down, a plurality of needle pedestals 941˜943 arranged in three columns up and down, a plurality of adhesive members 951˜953 arranged in three columns up and down, a plurality of connection portions 931˜933 arranged in three columns up and down, and a plurality of conductors 961˜963 arranged in three columns up and down.

In this way, the auxiliary card 901 includes the plurality of probe needles 921˜923 arranged in a plurality of columns up and down so that an IC chip 1001 having a structure in which a plurality of pads 1011 are arranged in three columns at one surface of the IC chip 1001, as illustrated in FIG. 10, can be tested at one time. Thus, costs and time for a test are reduced.

It is noted that the IC chip 1001 illustrated in FIG. 10 must be tested three times using the conventional probe card 101. However, when using the auxiliary card 901 illustrated in FIG. 9, the IC chip 1001 illustrated in FIG. 10 can be tested at one time.

As described above, according to the present invention, an auxiliary card is mounted on and detached from the main card. That is, only the auxiliary card can be replaced according to types of IC chips. The auxiliary card has a simple structure and costs for manufacturing the auxiliary card are low and manufacturing duration thereof is short. Thus, costs for manufacturing the probe card are reduced and productivity is improved due to reduction of manufacturing duration.

In addition, portions for adjusting the auxiliary card in the X-axis and the Y-axis, respectively, are provided in the main card such that an alignment error does not occur when the IC chip is tested.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A probe card, comprising:
a main card having a flat plate, a hole being formed in the flat plate;
an auxiliary card vertically mounted on the main card through the hole; and
a plurality of probe needles attached to the auxiliary card.

2. The probe card of claim 1, wherein the auxiliary card can be mounted on and detached from the main card.

3. The probe card of claim 1, comprising a substrate mounting portion installed on the main card and combined with the auxiliary card and, the substrate mounting portion fixing the auxiliary card on the main card.

4. The probe card of claim 1, wherein a plurality of auxiliary cards are mounted on the main card.

5. The probe card of claim 1, wherein the probe card is used in testing an IC (integrated circuit) chip disposed on a wafer.

6. The probe card of claim 1, wherein the main card comprises a plurality of electrical conductors and the auxiliary card comprises a plurality of connection portions for electrically connecting the plurality of electrical conductors to the plurality of probe needles.

7. The probe card of claim 6, wherein the auxiliary card further comprises a plurality of conductors for electrically connecting the plurality of connection portions to the plurality of probe needles.

8. The probe card of claim 6, wherein the plurality of connection portions are connectors that can be connected to and detached from the plurality of probe needles.

9. The probe card of claim 1, wherein the plurality of probe needles are formed in a straight line shape.

10. The probe card of claim 1, wherein the auxiliary card further comprises a plurality of needle pedestals, the plurality of needle pedestals provided between the plurality of needles and the auxiliary card and supporting the plurality of needles upwards so that the plurality of needles can be inclined with respect to the auxiliary card.

11. A probe card, comprising:
a main card having a flat plate, a hole being formed in the flat plate;
an auxiliary card vertically mounted on the main card through the hole;
a plurality of probe needles attached to the auxiliary card; and
an adjusting portion installed above the main card and moving the auxiliary card forward and backward.

12. The probe card of claim 11, wherein the main card is installed on the adjusting portion and comprises a substrate mounting portion on which the auxiliary card is mounted.

13. The probe card of claim 11, wherein the main card comprises a pedestal installed below the adjusting portion, the pedestal fixing the adjusting portion on the main card.

14. The probe card of claim 11, wherein a plurality of auxiliary cards and a plurality of adjusting portions are respectively provided.

15. A probe card, comprising:
a main card having a flat plate, a hole being formed in the flat plate;
an auxiliary card vertically mounted on the main card through the hole;
a plurality of probe needles attached to the auxiliary card; and
an X-axis adjusting portion installed above the main card and moving the auxiliary card in an X-axis; and
an Y-axis adjusting portion installed below the X-axis adjusting portion and moving the X-axis adjusting portion in an Y-axis.

16. The probe card of claim 15, wherein the main card is installed on the X-axis adjusting portion and comprises a substrate mounting portion on which the auxiliary card is mounted.

17. The probe card of claim 15, wherein the main card comprises a pedestal installed below the Y-axis adjusting portion and fixing the Y-axis adjusting portion on the main card.

18. The probe card of claim 15, wherein a plurality of auxiliary cards, a plurality of X-axis adjusting portions, and a plurality of Y-axis adjusting portions are respectively provided.

19. A probe card, comprising:
a main card having a flat plate, a hole being formed in the flat plate;
an auxiliary card vertically mounted on the main card through the hole;
a plurality of probe needles attached to the auxiliary card;
a probe needle which is attached to the auxiliary card and to which a power supply voltage is applied; and
a power restricting portion electrically connected to the probe needle to which the power supply voltage is applied and preventing an overvoltage or overcurrent from being applied to the probe needle to which the power supply voltage is applied.

20. The probe card of claim 19, wherein the power restricting portion is a capacitor.
